(19) United States
(12) Patent Application Publication
(10) Pub. No.: US 2006/0138570 A1
(43) Pub. Date: Jun. 29, 2006

(54) Semiconductor device and fabricating method thereof

(76) Inventor: Jae Hee Kim, Gyeonggi-do (KR)

Correspondence Address: THE LAW OFFICES OF ANDREW D. FORTNEY, PH.D., P.C., 7257 N. MAPLE AVENUE, BLDG. D, SUITE 107, FRESNO, CA, 93720, US

(21) Appl. No.: 11/317,987

(22) Filed: Dec. 22, 2005

(30) Foreign Application Priority Data
Dec. 23, 2004 (KR) 10-2004-0111157

(51) Int. Cl. H01L 29/94; H01L 29/76

(52) U.S. Cl. 257/411; 257/288; 257/408; 257/344

(57) ABSTRACT

A semiconductor device and semiconductor device fabricating method may enhance device reliability by forming a chemical oxide buffer layer prior to forming a high-k gate oxide layer. The semiconductor device includes a semiconductor substrate; a chemical oxide buffer layer on the semiconductor substrate; a high-k gate oxide layer on the buffer layer; a gate electrode formed on the high-k gate oxide layer; and lightly doped drain and source/drain regions formed in a surface of the semiconductor substrate beside the gate electrode. By forming the buffer layer of chemical oxide on the semiconductor substrate and by forming the gate oxide layer on the buffer layer, a stable high-k material can be provided at the interface between the high-k gate oxide layer and the semiconductor substrate.

This application claims the benefit of Korean Patent Application No. 10-2004-0111157, filed on Dec. 23, 2004, which is hereby incorporated by reference as if fully set forth herein.

### BACKGROUND OF THE INVENTION

1. Field of the Invention

The present invention relates to a semiconductor device, and more particularly, to a semiconductor device and fabricating method thereof. Although the present invention is suitable for a wide scope of applications, it is particularly suitable for enhancing reliability of the semiconductor device by forming a chemical oxide buffer layer, prior to forming a gate oxide layer to provide a gate oxide layer of a stable, high-k material.

2. Discussion of the Related Art

The fabrication of a high-capacity semiconductor memory device such as a MOSFET or a DRAM requires the formation of a very thin coating of a material having a high dielectric constant (k) on a semiconductor wafer (substrate) as a gate oxide layer. This gate dielectric layer has typically been formed from silicon dioxide (SiO₂), but to scale down such memory devices, dielectrics having a having dielectric constant (k value) higher than that of silicon dioxide are needed or desired. To this end, nitrides have been considered to reach the desired very thin gate dielectric layer thickness (e.g., below 20 Å), without excessively degrading gate leakage current characteristics.

For instance, in a known method for forming a dielectric layer, an oxynitride layer is formed on a substrate and is then annealed in an oxygen or inert gas ambient. The dielectric layer is formed by growing a silicon dioxide layer on a heated surface of a semiconductor substrate exposed to nitrogen dioxide (N₂O) to impart the surface layer with a nitrogen component. The silicon dioxide layer is then heated to form silicon-nitrogen bonds at an interface between the silicon dioxide layer and the semiconductor substrate. Finally, the layer is annealed in an inert ambient, such as one of nitrogen gas. This method provides some advantage, but k values even higher than the k value of the layer ultimately produced by this method may be desired.

Therefore, in another known method, the dielectric layer is formed by forming a base oxide layer on a semiconductor substrate and attaching a gate contact material to a gate dielectric to form a gate stack. Further scaling down the technology, however, is expected to require oxide thicknesses of less than 2 μm (for 100 nm technology) or even 1 nm (for 50 nm technology). Thus, although gate dielectric layers of silicon oxide could theoretically reach such a small size, the gate leakage (due to tunneling current of a gate layer) for a dielectric layer of silicon oxide would be unacceptably high. Hence, to reduce the tunneling current, a material having a high k value is needed.

Meanwhile, high-k gate oxides layers may be formed as a stacked structure of silicon dioxide and either hafnium oxide (HfO₂) or aluminum oxide (Al₂O₃), or as a laminate structure of silicon oxynitride (or silicon nitride) and either hafnium oxide or aluminum oxide, and such a high-k structures may be brought into direct contact with a semiconductor substrate. Therefore, a nitrogen-hydrogen charge trap site may be generated or included to degrade a negative-bias temperature instability characteristic. If one attempts to solve this problem by providing silicon dioxide to an interface between a high-k material and a silicon substrate, the interface characteristics with respect to the substrate can become poor and can seriously degrade reliability. Hence, various additional processes may be needed to enhance the interface characteristics. Moreover, since silicon dioxide can be considered to be a low-k material, it may reduce the effect of using a high-k material.

### SUMMARY OF THE INVENTION

Accordingly, the present invention is directed to a semiconductor device and fabricating method thereof that substantially obviate one or more problems due to limitations and disadvantages of the related art.

An object of the present invention is to provide a semiconductor device and fabricating method thereof, by which reliability of the semiconductor device is enhanced, by forming a chemical oxide buffer layer prior to forming a high-k gate oxide layer.

Another object of the present invention is to provide a semiconductor device and fabricating method thereof, which enables the formation of a gate oxide layer exhibiting a high dielectric constant that is stable.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages in accordance with the purpose of the invention, as embodied and broadly described herein, there is provided a semiconductor device comprising a semiconductor substrate; a buffer layer of chemical oxide formed on the semiconductor substrate; a high-k gate oxide layer formed on the buffer layer; a gate electrode formed on the high-k gate oxide layer; and lightly doped drain and source/drain regions formed in a surface of the semiconductor substrate beside the gate electrode.

In another aspect of the present invention, there is provided a method of fabricating a semiconductor device, the method comprising forming a buffer layer of chemical oxide on a semiconductor substrate; forming a high-k gate oxide layer on the buffer layer; forming a gate electrode on the high-k gate oxide layer; and forming lightly doped drain and source/drain regions in a surface of the semiconductor substrate beside the gate electrode.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle(s) of the invention. In the drawings:

FIG. 1 is a cross-sectional diagram of a semiconductor substrate, showing a step of removing a native oxide from the semiconductor substrate in a method for fabricating a semiconductor device according to the present invention;

FIG. 2 is a cross-sectional diagram of a semiconductor substrate, showing a step of removing metallic impurities from the semiconductor substrate in a method for fabricating a semiconductor device according to the present invention;

FIG. 3 is a cross-sectional diagram of a semiconductor substrate, showing a step of forming a buffer layer on the semiconductor substrate in a method for fabricating a semiconductor device according to the present invention;

FIG. 4 is a cross-sectional diagram of a semiconductor substrate, showing a step of forming a gate oxide layer on a buffer layer in a method for fabricating a semiconductor device according to the present invention;

FIG. 5 is a cross-sectional diagram of a semiconductor substrate, showing steps of forming a gate electrode on the buffer layer and forming lightly doped drain regions beside the gate electrode in a method for fabricating a semiconductor device according to the present invention; and

FIG. 6 is a cross-sectional diagram of a semiconductor substrate, showing steps of forming source/drain regions in a method for fabricating a semiconductor device according to the present invention.

### DETAILED DESCRIPTION OF THE INVENTION

Reference will now be made in detail to the preferred embodiments of the present invention, examples of which are illustrated in the accompanying drawings. Wherever possible, like reference designations will be used throughout the drawings to refer to the same or similar parts.

According to the present invention, a buffer layer of chemical oxide is formed on a substrate during a cleaning process that is generally performed prior to the formation of a high-k gate oxide layer. That is, in a cleaning process to remove a native oxide layer from the surface of the substrate, a chemical oxide buffer layer may be formed (typically, following the removal of the native oxide). Accordingly, by effectively substituting a chemical oxide buffer layer for the native oxide, a stable high-k material can be provided at an interface between a semiconductor substrate and a high-k gate oxide layer to be formed later.

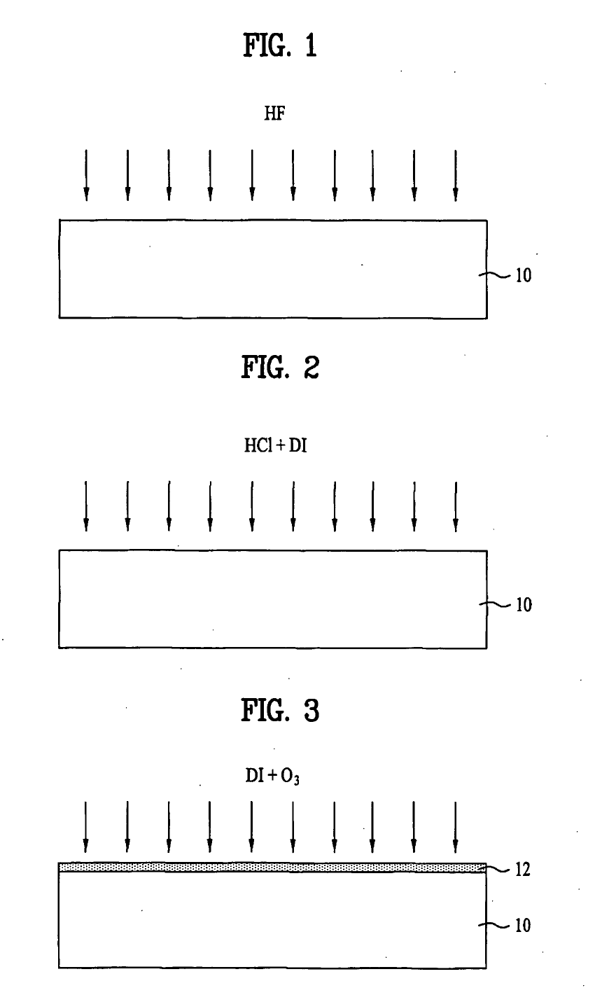

FIGS. 1-6 illustrate a method of fabricating a semiconductor device including its gate oxide layer according to an exemplary embodiment of the present invention.

Referring to FIG. 1, prior to the formation of a high-k gate oxide layer, a layer of native oxide (not shown) existing on the surface of a semiconductor substrate 10 (e.g., a single-crystal silicon wafer, an epitaxial silicon or silicon-germanium layer, etc.) is removed in a cleaning process using a diluted solution of hydrofluoric acid (HF). The dilute solution of hydrofluoric acid (HF) may comprise or consist essentially of an aqueous HF solution or a buffered oxide etch solution (e.g., dilute aqueous HF further containing an ammonia or ammonium hydroxide buffer) conventionally used in semiconductor manufacturing for removing silicon oxides.

Referring to FIG. 2, as part of the cleaning process, metallic impurities are removed from the surface of the semiconductor substrate 10 using a first mixture of hydrogen chloride (HCl) and deionized water (DI), in which the concentration of hydrogen chloride may be about 0.3˜1.0 wt %. The temperature of the first mixture is generally room temperature (e.g., from about 15° C. to about 30° C., and more typically, about 25° C.).

In FIG. 3, the cleaning process may be completed by the application of a second mixture of deionized (DI) water and ozone (O₃) to the semiconductor substrate 10 from which the native oxide and metallic impurities have been removed, thereby forming a buffer layer 12 comprising or consisting essentially of a chemical oxide on the semiconductor substrate. The chemical oxide buffer layer 12 thus generally comprises or consisting essentially of a reaction product of deionized water and ozone with a surface material of the semiconductor substrate 10. Typically, this reaction product is primarily silicon dioxide having one or more characteristics of the reaction between an ozone/DI water mixture and single-crystal silicon. The ozone concentration in the second mixture is generally at least 0.5 ppm, and the temperature of the second mixture is also generally about room temperature (e.g., about 25° C.). The buffer layer 12 is formed to a thickness of 7˜10 Å by submerging (dipping) the semiconductor substrate 10 in the second mixture for at least 300 seconds. It is believed that such conditions may maintain the ozone concentration in a state of “over flow.” However, as is known in the art, one may empirically derive a rate for chemical oxide formation (e.g., thickness as a function of time) for a given set of reaction conditions, then determine an appropriate length of time for the reaction that provides a desired chemical oxide thickness.

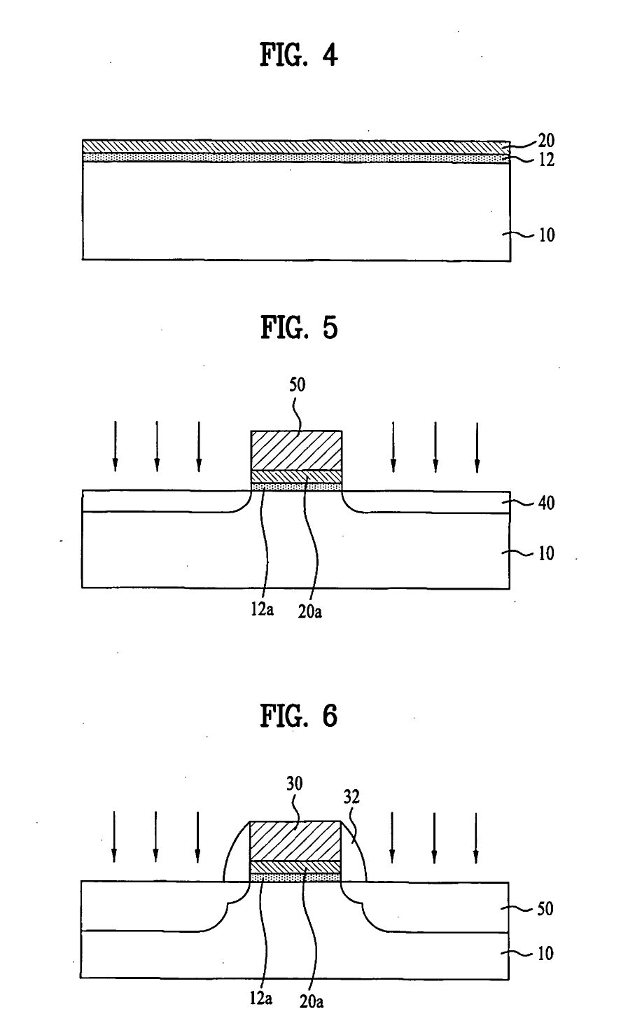

Referring to FIG. 4, a gate oxide layer 20 comprising or consisting essentially of a high-k material is formed on the chemical oxide buffer layer 12, which has been formed on the semiconductor substrate 10 by the cleaning process. That is, the high-k gate oxide layer 20 contacts the semiconductor substrate 10 via the chemical oxide buffer layer 12. The gate oxide layer 20 is formed on an active area of the semiconductor substrate 10 by high-temperature thermal oxidation (which may be wet or dry), and is then annealed at a higher temperature in a gas ambient of a nitrogen oxide (NO and/or N₂O), which may form some silicon-nitrogen bonds in the gate oxide layer 20 and/or in the chemical oxide buffer layer 12 (and possibly at the interface between the chemical oxide buffer layer 12 and the substrate 10). As a result, the gate oxide layer 20 and/or the chemical oxide buffer layer 12 may comprise or consist essentially of a silicon oxynitride, which may provide a higher k value to the buffer layer 12. The gate oxide layer 20 of the present invention is thus provided with a stacked or laminate structure. The high-k gate oxide layer 20 generally has a thickness of from 10 to 40 Å, preferably 10 to 20 Å.

Referring to FIG. 5, a gate electrode 30 is formed on a predetermined area of the gate oxide layer 20, which is patterned together with the buffer layer 12 at the time of patterning the gate electrode. That is, the gate electrode is formed by depositing a polysilicon layer (not shown) over the semiconductor substrate 10 including the gate oxide layer 20 and the buffer layer 12, and selectively etching the deposited polysilicon layer by photolithography, such that a gate oxide layer pattern 20a and a buffer layer pattern 12a are disposed under the gate electrode 30. As is known in the art, the polysilicon layer that forms the gate electrode 30 may be etched with a first etchant that selectively removes polysilicon relative to silicon dioxide or a silicon oxynitride, then the gate oxide layer 20 and the chemical oxide buffer layer 12 may be etched with a second etchant that selectively removes silicon dioxide or a silicon oxynitride relative to crystalline silicon or polysilicon. Lightly doped drain regions 40 are formed by implanting a light dose of impurities in the surface of the semiconductor substrate 10 beside the gate electrode 30; that is, using the gate electrode as a mask.

Referring to FIG. 6, an insulating layer (not shown) is deposited on the semiconductor substrate 10. The insulating layer may comprise silicon dioxide, silicon nitride, or a layered combination thereof (e.g., a relatively thick silicon nitride layer on a relatively thin silicon dioxide buffer layer). The insulating layer is etched back to form an insulating sidewall 32 on both lateral sides of the gate electrode 30. Source/drain regions 50 (which are generally heavily doped) are formed by implanting a relatively large dose of impurities using the gate electrode 30 and the insulating sidewall 32 as a mask.

As mentioned in the foregoing description, in the semiconductor device and fabricating method thereof according to the present invention, the buffer layer 12 of chemical oxide is formed after the native oxide has been removed from the semiconductor substrate 10 by a cleaning process that is generally performed prior to forming the gate oxide layer 20 on the semiconductor substrate. Thus, a chemical oxide buffer layer is formed on the surface of a semiconductor substrate, thereby providing a stable (and preferably high-k) material to the interface between the high-k gate oxide layer and the semiconductor substrate.

By forming the chemical oxide buffer layer on the semiconductor substrate and by forming the gate oxide layer on the buffer layer, a stable (and preferably high-k) material can be provided to the interface between the substrate and the high-k gate oxide layer. In addition, since the high-k gate oxide layer is brought into contact with the semiconductor substrate via the chemical oxide buffer layer, a negative-bias temperature instability degradation, which may occur due to energy potential variations of the gate oxide layer, can be reduced, minimized or prevented to thereby enable on-current increases of at least 20%. Hence, the present invention can enhance the reliability of the semiconductor device.

It will be apparent to those skilled in the art that various modifications can be made in the present invention without departing from the spirit or scope of the invention. Thus, it is intended that the present invention covers such modifications provided they come within the scope of the appended claims and their equivalents.

What is claimed is:

1. A semiconductor device, comprising:
a semiconductor substrate;
a chemical oxide buffer layer on the semiconductor substrate;
a high-k gate oxide layer on the buffer layer;
a gate electrode on the high-k gate oxide layer; and
lightly doped drain and source/drain regions in a surface of the semiconductor substrate adjacent to the gate electrode.

2. The semiconductor device of claim 1, wherein the buffer layer comprises a reaction product of deionized water and ozone with a surface material of the semiconductor substrate.

3. The semiconductor device of claim 2, wherein the buffer layer consists essentially of the reaction product.

4. The semiconductor device of claim 1, wherein the buffer layer has a thickness of 7˜10 Å.

5. The semiconductor device of claim 1, wherein the high-k gate oxide layer comprises a thermal silicon dioxide or a silicon oxynitride.

6. The semiconductor device of claim 1, wherein the high-k gate oxide layer has a thickness of from 10 to 40 Å.

7. A method of fabricating a semiconductor device, comprising:
forming a chemical oxide buffer layer on a semiconductor substrate;
forming a high-k gate oxide layer on the buffer layer;
forming a gate electrode on the high-k gate oxide layer;
forming lightly doped drain regions in a first surface of the semiconductor substrate adjacent to the gate electrode; and
forming source/drain regions in a second surface of the semiconductor substrate adjacent to the gate electrode.

8. The method of claim 7, wherein the buffer layer has a thickness of 7˜10 Å.

9. The method of claim 7, wherein forming the chemical oxide buffer layer comprises:
removing a native oxide from the semiconductor substrate using a chemical substance;
removing metallic impurities from the semiconductor substrate using a first mixture; and
forming the buffer layer of chemical oxide using a second mixture.

10. The method of claim 9, wherein the chemical substance comprises hydrofluoric acid.

11. The method of claim 9, wherein the first mixture includes hydrogen chloride and deionized water.

12. The method of claim 11, wherein the hydrogen chloride has a concentration of 0.3˜1.0 wt %.

13. The method of claim 9, wherein the second mixture includes deionized water and ozone.

14. The method of claim 13, wherein the ozone has a concentration of at least 0.5 ppm.

15. The method of claim 13, wherein forming the buffer layer comprises submerging the semiconductor substrate in the second mixture for at least 300 seconds.

16. The method of claim 13, wherein forming the buffer layer further comprises maintaining the ozone concentration in a state of over flow.

17. The method of claim 7, wherein the high-k gate oxide layer comprises thermal silicon dioxide or a silicon oxynitride.

18. The method of claim 7, wherein the high-k gate oxide layer has a thickness of from from 10 to 40 Å.
